(19) United States
(12) Patent Application Publication
(10) Pub. No.: US 2011/0062020 A1
(43) Pub. Date: Mar. 17, 2011

(54) Rotary Target Assembly and Rotary Target

(75) Inventors: Chung-Han Wu, Tainan (TW); Wel-Hsun Hsu, Tainan (TW); I-Sheng Wu, Tainan (TW)

(73) Assignee: SOLAR APPLIED MATERIALS TECHNOLOGY CORP, Tainan (TW)

(21) Appl. No.: 12/585,421

(22) Filed: Sep. 15, 2009

(51) Int. Cl. C23C 14/34

(52) U.S. Cl. 204/298.12

(57) ABSTRACT

A rotary target assembly has a cylindrical target and a cylindrical backing tube. A difference between an inner diameter of the cylindrical target and an outer diameter of the cylindrical backing tube substantially equals a yield strain of a target material multiplied by the inner diameter of the cylindrical target and multiplied by N, wherein N is between 1 and 10. The difference can be adjusted according to the target material, dimension of the cylindrical target, so the cylindrical target can be combined tightly with cylindrical backing tube. A resulting rotary target of the present invention has improved thermal and electrical conductivities.

### BACKGROUND OF THE INVENTION

1. Field of Invention

The present invention relates to a rotary target, and more particularly to a rotary target that has a cylindrical target and a cylindrical backing tube combined tightly.

2. Description of the Related Art

Generally, a flat target is used in a magnetron sputtering procedure. Sputtering is performed on a target surface of the flat target and is concentrated on an area of highest plasma density where magnetic field lines are tangent to the target surface. Consequently, race-track erosion patterns will be formed on the target surface after sputtering. The flat target has a use rate of only about 35%˜50%.

Therefore, a rotary target was provided in the magnetron sputtering procedure, which has an even erosion surface, so a thin film made of the rotary target is uniform. A use rate of the rotary target is up to 70%˜80% and has an elongated life to decrease cost of sputtering and cost for purchasing a new rotary target.

The rotary target has a cylindrical target and a cylindrical backing tube. To combine the cylindrical target and the cylindrical backing tube of the rotary target is more complicated than to combine a target material and a backing plate of a flat target. A common method to combine the cylindrical target and the cylindrical backing tube comprises providing a cylindrical target and a cylindrical backing tube with an outer diameter smaller than an inner diameter of the cylindrical target, inserting the cylindrical backing tube into the cylindrical target and applying solder made of metal with low melting point to an interval between the cylindrical target and the cylindrical backing tube to combine the cylindrical target and the cylindrical backing tube. Although the metal with low melting point has low thermal stress, it is hard to apply pressure to the rotary target when soldering the cylindrical target and the cylindrical backing tube, so the cylindrical target cannot be combined tightly with the cylindrical backing tube. Sometimes, the cylindrical target is detached from the cylindrical backing tube at a specific temperature.

Other methods to combine the cylindrical target and the cylindrical backing tube include spray plating, casting or electroplating.

Spray plating comprises plating material of the cylindrical target onto an outer surface of the cylindrical backing tube by plasma or under high pressure to form the rotary target, but it easily results is forming pores in the cylindrical target to lower a density of the cylindrical target.

Casting comprises using a tubular mold surrounding the cylindrical backing tube and pouring material of the cylindrical target into an interval between the tubular mold and the cylindrical backing tube to form the rotary target. However, the material of the cylindrical target is limited to a material with low melting point.

Electroplating comprises putting the cylindrical backing tube into an electroplating bath with material of the cylindrical target and allowing the material to deposit onto a surface of the cylindrical backing tube to form the rotary target. Although the material of the cylindrical target adheres tightly to the cylindrical backing tube, electroplating takes a long time and a deposit thickness is limited.

U.S. Pat. No. 5,435,965 discloses a method for manufacturing a sputtering target comprising inserting a cylindrical backing member into a mold such that a space is defined between the backing member and the mold, filling a target material into the space between the backing member and the mold. Thereafter, the target material and the backing member are subjected to hot isostatic pressing to elevate a density of the target material. However, equipment for hot isostatic pressing is expensive, which increases manufacturing costs of the sputtering target.

JP 11-71667 discloses a method for manufacturing a rotary target comprising inserting the cylindrical backing tube into the cylindrical target according to the theory of thermal expansion and contraction and using mechanical force to combine the cylindrical backing tube and the cylindrical target. A difference between the inner diameter of the cylindrical target and the outer diameter of the cylindrical backing tube is from 0.01 mm to 0.5 mm, but an association between the difference and a dimension of the rotary target is never considered. According to George M. Wityak's research (performance comparison of silver sleeved rotary targets with planar targets, George M. Wityak, Society of Vacuum Coaters, 49^{th} Annual Technical Conference Proceedings, 2005), although the difference and a dimension of the rotary target are not adjusted suitably and the cylindrical target and the cylindrical backing tube may not be detached from each other, it can be observed that the rotary target has poor thermal and electrical conductivities according to a variation of temperature of the rotary target and generation frequency of electric arc.

Furthermore, US Publication No. 2004/0074770 discloses a method for manufacturing the rotary target comprising providing a backing tube and a rotary target segment with an inner diameter slightly smaller and substantially equal to an outside diameter of the backing tube, heating and expanding the rotary target segment, placing or slipping the rotary target segment onto the backing tube, and cooling the rotary target segment to form the rotary target. However, properties of material of the cylindrical target and a dimension of the rotary target are not considered in the method, so the rotary target segment and the backing tube cannot be combined tightly.

To overcome the shortcomings, the present invention provides a rotary target to mitigate or obviate the aforementioned.

### SUMMARY OF THE INVENTION

The primary objective of the present invention is to provide a rotary target assembly that forms a rotary target with a cylindrical target and a cylindrical backing tube combined tightly.

To achieve the objective, the rotary target assembly in accordance with the present invention comprises a cylindrical target and a cylindrical backing tube. A difference between an inner diameter of the cylindrical target and an outer diameter of the cylindrical backing tube substantially equals a yield strain of a target material multiplied by the inner diameter of the cylindrical target and multiplied by N, wherein N is between 1 and 10.

The difference can be adjusted according to the target material, dimension of the cylindrical target, so the cylindrical target can be combined tightly with cylindrical backing tube. A resulting rotary target of the present invention has improved thermal and electrical conductivities.

Other objectives, advantages and novel features of the invention will become more apparent from the following detailed description when taken in conjunction with the accompanying drawings.

### BRIEF DESCRIPTION OF THE DRAWINGS

FIG. 1 is an explosive perspective view of a rotary target assembly in accordance with the present invention;

FIG. 2 is an end view of a cylindrical backing tube of the rotary target assembly in accordance with the present invention;

FIG. 3 is an end view of a cylindrical target of the rotary target assembly in accordance with the present invention;

FIG. 4 is an explosive perspective view of one embodiment of the rotary target assembly in accordance with the present invention; and

FIG. 5 is an explosive perspective view of another embodiment of the rotary target assembly in accordance with the present invention.

### DETAILED DESCRIPTION OF THE INVENTION

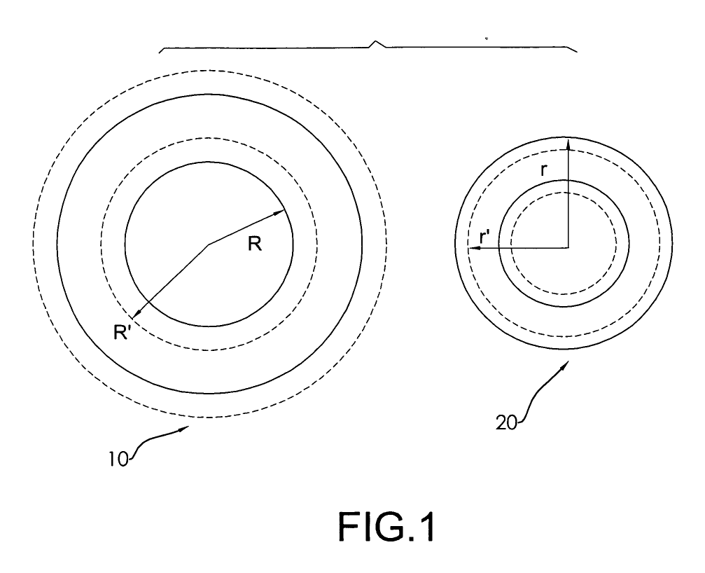

With reference to FIG. 1, a rotary target assembly in accordance with the present invention has a cylindrical target (10) and a cylindrical backing tube (20). The cylindrical target (10) serves as an outer tube, is made of a target material and has an inner diameter. The cylindrical backing tube (20) serves as an inner tube, is used to insert into the cylindrical target (10) and has an outer diameter. The inner diameter of the cylindrical target (10) is smaller than the outer diameter of the cylindrical backing tube (20). A difference between the inner diameter of the cylindrical target (10) and the outer diameter of the cylindrical backing tube (20) substantially equals a yield strain of the target material multiplied by the inner diameter of the cylindrical target (10) and multiplied by N, wherein N is between 1 and 10.

The target material and material for the cylindrical backing tube (20) are respectively selected from the group consisting of metal, alloy, ceramic, nitride, oxide and a combination thereof.

R and r respectively present the inner diameter of the cylindrical target (10) and the outer diameter of the cylindrical backing tube (20) and r>R. When heat is applied, a temperature difference occurs between the cylindrical target (10) and the cylindrical backing tube (20). According to the theory of thermal expansion and contraction, R′ substantially equals R (1+KₐTₐ) and r′ substantially equals r (1+K_{b}T_{b}), wherein R′ and r′ respectively present the inner diameter of the cylindrical target (10) and the outer diameter of the cylindrical backing tube (20) after expansion or contraction of the cylindrical target (10) and/or the cylindrical backing tube (20); Kₐ and K_{b} respectively present coefficients of thermal expansion of the cylindrical target (10) and the cylindrical backing tube (20); Tₐ and T_{b} respectively present temperature differences of temperatures of the cylindrical target (10) and temperatures of the cylindrical backing tube (20) before and after expansion or contraction. When R′>r′, the cylindrical backing tube (20) can be inserted into the cylindrical target (10).

The difference between the inner diameter of the cylindrical target (10) and the outer diameter of the cylindrical backing tube (20) decides a tightness of the cylindrical target (10) and the cylindrical backing tube (20) and endurable stresses of the cylindrical target (10) and the cylindrical backing tube (20).

A preferred difference of the present invention should equal a yield strain of the target material multiplied by the inner diameter of the cylindrical target (10) and multiplied by N, wherein N is between 1 and 10. When the difference was smaller than the preferred difference, a cylindrical target and a cylindrical backing tube cannot be combined tightly and a resulting rotary target has poor thermal and electrical conductivities, so a temperature of the rotary target was undesirably raised and the rotary target discharges abnormally. When the difference was larger than the preferred difference, the rotary target was deformed and damaged and could not be used.

The cylindrical target (10) and the cylindrical backing tube (20) can be combined tightly without applying any solder. In order to further enhance thermal and electrical conductivities and combination of the cylindrical target (10) and the cylindrical backing tube (20), a medium can be applied on an inner surface of the cylindrical target (10) or an outer surface of the cylindrical backing tube (20), or both before the cylindrical backing tube (20) is inserted into the cylindrical target (10).

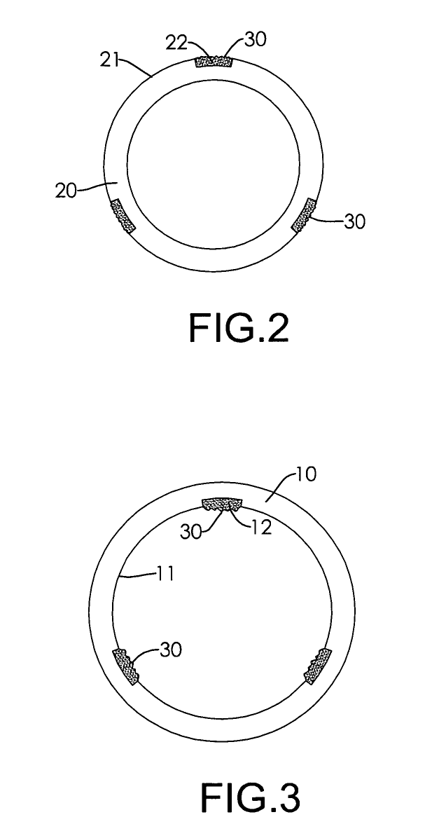

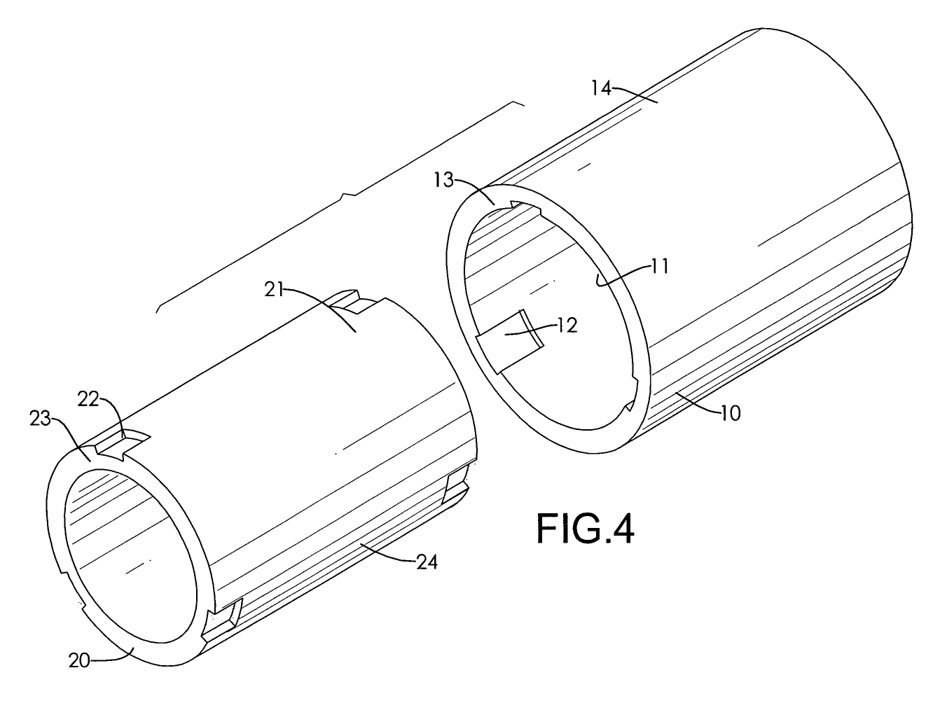

With reference to FIGS. 2 and 3, the cylindrical target (10) has an inner surface (11) and at least one inner groove (12). The inner groove (12) is formed in the inner surface (11) of the cylindrical target (10) and may be filled with medium (30). The cylindrical backing tube (20) has an outer surface (21) and at least one outer groove (22). The outer groove (22) is formed in the outer surface (21) and may be filled with medium (30). The medium (30) is made of electrically conductive material such as solder. The medium (30) can be applied into the inner groove (12) and/or the outer groove (22) before or after the cylindrical target (10) and the cylindrical backing tube (20) are assembled.

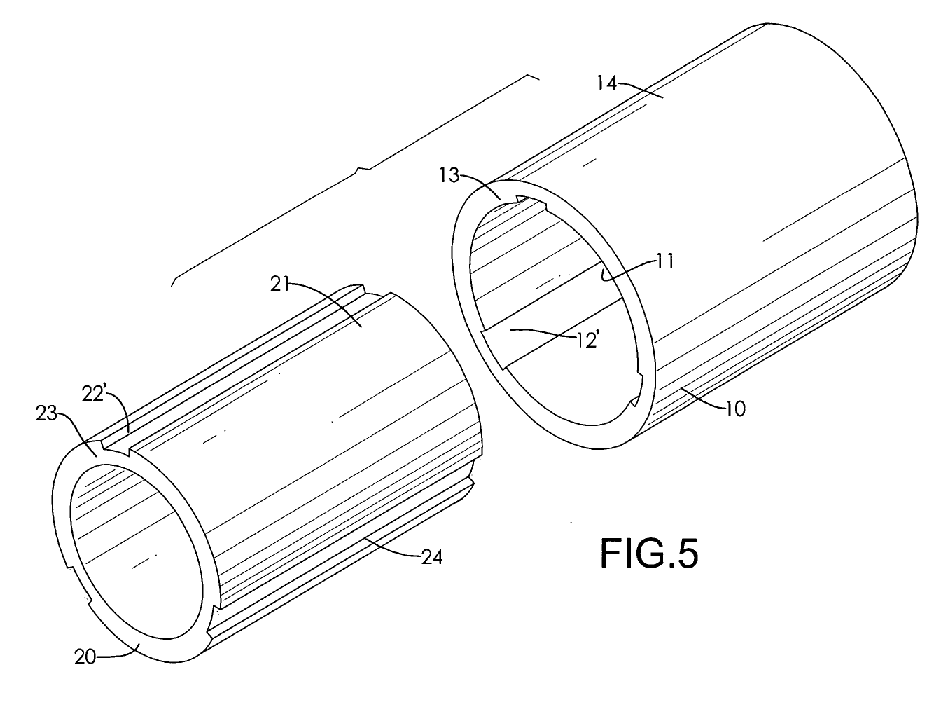

With reference to FIG. 4, in one embodiment, the cylindrical target (10) has a proximal end (13), a distal end (14), an inner surface (11) and at least one inner groove (12). The inner grooves (12) are formed in the inner surface (11) adjacent to the proximal end (13) or the distal end (14) of the cylindrical target (10). The cylindrical backing tube (20) has a proximal end (23), a distal end (24), an outer surface (21) and at least one outer grooves (22). The outer grooves (22) are formed in the outer surface (21) respectively adjacent to the proximal end (23) or the distal end (24) of the cylindrical backing tube (20).

The inner grooves (12) respectively adjacent to the proximal end (13) and the distal end (14) may be formed at intervals or may communicate with each other to form an annular groove. The outer grooves (22) respectively adjacent to the proximal end (23) and the distal end (24) may be formed at intervals or may communicate with each other to form an annular groove.

With reference to FIG. 5, in another embodiment, each inner groove (12′) is longitudinally formed in the inner surface (11) from the proximal end (13) to the distal end (14) for receiving more medium. Each outer groove (22′) is longitudinally formed in the outer surface (21) from the proximal end (23) to the distal end (24). Each inner groove (12′) or each outer groove (22′) may be linear, spiral or the like.

The present invention also provides a rotary target that comprises the rotary target assembly. The cylindrical backing tube (20) is mounted in and combined tightly with the cylindrical target (10).

### EXAMPLE

### Method for Manufacturing a Rotary Target

### Example 1

A cylindrical silver (Ag) target with a length of 1000.0 mm and an inner diameter of 132.5 mm and a cylindrical stainless steel backing tube with a length of 1400.0 mm and an inner diameter of 133.0 mm were provided. A coefficient of thermal expansion of Ag is about 19.5×10⁻⁶/K. The cylindrical Ag target was heated from room temperature (25° C.) to 500° C. and the inner diameter expanded to 133.7 mm. The cylindrical stainless steel backing tube was maintained at 25° C. and was inserted into the cylindrical Ag target to form a rotary target. The rotary target was cooled to a room temperature and the cylindrical Ag target and the cylindrical stainless steel backing tube were combined tightly. A difference between the cylindrical Ag target and the cylindrical stainless steel backing tube is 0.5 mm, a yield strain of Ag is 0.25% and N is 1.5. Runout and perpendicularity of the rotary target both were smaller than 0.05 mm and concentricity of the rotary target was smaller than 1.0 mm.

### Example 2

A cylindrical indium tin oxide (ITO) target with a length of 850.0 mm and an inner diameter of 70.0 mm and a cylindrical stainless steel backing tube with a length of 1000.0 mm and an inner diameter of 70.15 mm were provided. A coefficient of thermal expansion of ITO is about 7.5×10⁻⁶/K and that of stainless steel is about 10.5×10⁻⁶/K. The cylindrical ITO target was heated from room temperature (25° C.) to 525° C. and the inner diameter expanded to 70.26 mm. The cylindrical stainless steel backing tube was cooled from 25° C. to −75° C. and the outer diameter of the cylindrical stainless steel backing tube contracted to 70.08. The cylindrical stainless steel backing tube was inserted into the cylindrical ITO target to form a rotary target. The rotary target was cooled to room temperature and the cylindrical ITO target and the cylindrical stainless steel backing tube were combined tightly. A difference between the cylindrical ITO target and the cylindrical stainless steel backing tube is 0.15 mm, a yield strain of ITO is 0.21% and N is 1.0. Runout and perpendicularity of the rotary target both were smaller than 0.05 mm and concentricity of the rotary target was smaller than 1.0 mm.

### Example 3

A cylindrical aluminum (Al) target with a length of 1000.0 mm and an inner diameter of 100.0 mm and a cylindrical stainless steel backing tube with a length of 1400.0 mm and an inner diameter of 101.0 mm were provided. A coefficient of thermal expansion of Al is about 23.2×10⁻⁶/K. The cylindrical Al target was heated from room temperature (25° C.) to 525° C. and the inner diameter expanded to 101.2 mm. The cylindrical stainless steel backing tube was maintained at 25° C. and was inserted into the cylindrical Al target to form a rotary target. The rotary target was cooled to room temperature and the cylindrical Al target and the cylindrical stainless steel backing tube were combined tightly. A difference between the cylindrical Al target and the cylindrical stainless steel backing tube is 1.0 mm, a yield strain of Al is 0.21% and N is 4.0. Runout and perpendicularity of the rotary target both were smaller than 0.05 mm and concentricity of the rotary target was smaller than 1.0 mm.

### Comparative Example

A cylindrical silver (Ag) target with a length of 1000.0 mm and an inner diameter of 132.6 mm and a cylindrical stainless steel backing tube with a length of 1400.0 mm and an inner diameter of 132.8 mm were provided. A coefficient of thermal expansion of Ag is about 19.5×10⁻⁶/K. The cylindrical Ag target was heated from a room temperature (25° C.) to 500° C. and the inner diameter expanded to 133.8 mm. The cylindrical stainless steel backing tube was maintained at 25° C. and was inserted into the cylindrical Ag target to form a rotary target. The rotary target was cooled to a room temperature and the cylindrical Ag target and the cylindrical stainless steel backing tube were combined. A difference between the cylindrical Ag target and the cylindrical stainless steel backing tube is 0.2 mm, a yield strain of Ag is 0.25% and N is 0.6. Runout and perpendicularity of the rotary target both were smaller than 0.05 mm and concentricity of the rotary target was smaller than 1.0 mm.

Sputtering Test

Adjusting sputtering power from 1 kw to 5 kw, temperature of the cylindrical targets in examples 1, 2 and 3 were still maintained at 50° C. while temperature of the cylindrical target in the comparative example was higher than 150° C. It is proved that the cylindrical target and the cylindrical backing tube of the comparative example were not combined tightly, so heat cannot be transmitted from the cylindrical target to the cylindrical backing tube.

Therefore, a difference between the inner diameter of the cylindrical target and the outer diameter of the cylindrical backing tube has to be controlled to equal to a yield strain of the target material multiplied by the inner diameter of the cylindrical target and multiplied by N and N is between 1 and 10. The cylindrical target can be combined tightly with cylindrical backing tube. The rotary target of the present invention can be manufactured by simple procedure according to the theory of thermal expansion and contraction and has improved thermal and electrical conductivities.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A rotary target assembly, comprising:
a cylindrical target serving as an outer tube, made of a target material and having an inner surface and an inner diameter; and
a cylindrical backing tube serving as an inner tube, being used to insert into the cylindrical target and having an outer surface and an outer diameter that is larger than the inner diameter of the cylindrical target;
wherein before the cylindrical backing tube is combined with the cylindrical target, a difference between the inner diameter of the cylindrical target and the outer diameter of the cylindrical backing tube substantially equals a yield strain of the target material multiplied by the inner diameter of the cylindrical target and multiplied by N, wherein N is between 1 and 10.

2. The rotary target assembly as claimed in claim 1, wherein the target material and material for the cylindrical backing tube are independently selected from the group consisting of metal, alloy, ceramic, nitride, oxide and a combination thereof.

3. The rotary target assembly as claimed in claim 1, wherein the cylindrical target further has at least one groove formed in the inner surface of the cylindrical target.

4. The rotary target assembly as claimed in claim 1, wherein the cylindrical backing tube further has at least one groove formed in the outer surface of the cylindrical backing tube.

5. The rotary target assembly as claimed in claim 1, further having at least one groove formed in the inner surface of the cylindrical target; and at least one groove formed in the outer surface of the cylindrical backing tube.

6. The rotary target assembly as claimed in claim 1, further having a medium applied between the cylindrical target and the cylindrical backing tube and made of electrically conductive material.

7. The rotary target assembly as claimed in claim 2, further having a medium applied between the cylindrical target and the cylindrical backing tube and made of electrically conductive material.

8. The rotary target assembly as claimed in claim 3, wherein the groove is filled with a medium made of electrically conductive material.

9. The rotary target assembly as claimed in claim 4, wherein the groove is filled with a medium made of electrically conductive material.

10. The rotary target assembly as claimed in claim 5, wherein the groove formed in the inner surface of the cylindrical target and the groove formed in the outer surface of the cylindrical backing tube are filled with a medium made of electrically conductive material.

11. A rotary target, comprising
a cylindrical target serving as an outer tube, made of a target material and having an inner surface and an inner diameter; and
a cylindrical backing tube serving as an inner tube, mounted in and combined with the cylindrical target and having an outer surface and an outer diameter that is larger than the inner diameter of the cylindrical target before the cylindrical backing tube is combined with the cylindrical target;
wherein before the cylindrical backing tube is combined with the cylindrical target, the outer diameter of the cylindrical backing tube is larger than the inner diameter of the cylindrical target; and a difference between the inner diameter of the cylindrical target and the outer diameter of the cylindrical backing tube substantially equals a yield strain of the target material multiplied by the inner diameter of the cylindrical target and multiplied by N, wherein N is between 1 and 10.

12. The rotary target as claimed in claim 11, wherein the target material and material for the cylindrical backing tube are independently selected from the group consisting of metal, alloy, ceramic, nitride, oxide and a combination thereof.

13. The rotary target as claimed in claim 11, wherein the cylindrical target further has at least one groove formed in the inner surface of the cylindrical target.

14. The rotary target as claimed in claim 11, wherein the cylindrical backing tube further has at least one groove formed in the outer surface of the cylindrical backing tube.

15. The rotary target as claimed in claim 11, wherein there further has at least one groove formed in the inner surface of the cylindrical target; and at least one groove formed in the outer surface of the cylindrical backing tube.

16. The rotary target as claimed in claim 11, further having a medium applied between the cylindrical target and the cylindrical backing tube and made of electrically conductive material.

17. The rotary target as claimed in claim 12, further having a medium applied between the cylindrical target and the cylindrical backing tube and made of electrically conductive material.

18. The rotary target as claimed in claim 13, wherein the groove is filled with a medium made of electrically conductive material.

19. The rotary target as claimed in claim 14, wherein the groove is filled with a medium made of electrically conductive material.

20. The rotary target as claimed in claim 15, wherein the groove formed in the inner surface of the cylindrical target and the groove formed in the outer surface of the cylindrical backing tube are filled with a medium made of electrically conductive material.
